(19) United States
(12) Patent Application Publication
(10) Pub. No.: US 2026/0121372 A1
(43) Pub. Date: Apr. 30, 2026

(54) LIGHT SOURCE AND SILICON PHOTONICS SYSTEM INCLUDING THE SAME

(71) Applicant: SAMSUNG ELECTRONICS CO., LTD., Suwon-si (KR)

(72) Inventors: Changyoung PARK, Suwon-si (KR); Sanghun LEE, Suwon-si , Gyeonggi-do (KR)

(21) Appl. No.: 18/913,508

(22) Filed: Oct. 11, 2024

(30) Foreign Application Priority Data
Oct. 13, 2023 (KR) 10-2023-0137037

(51) Int. Cl. H01S 5/02; H01S 5/00; H01S 5/343

(52) U.S. Cl. CPC H01S 5/021; H01S 5/0071; H01S 5/0085; H01S 5/34366; H01S 2302/02

(57) ABSTRACT

A light source include a silicon substrate including a groove, an insulating layer provided on the silicon substrate and including a trench above the groove, a buffer layer filling the groove of the silicon substrate and the trench of the insulating layer, a light-emitting structure layer provided on the buffer layer and including a quantum well structure layer, a first lattice structure provided on the insulating layer and including a plurality of first lattices having a first arrangement period, and a second lattice structure provided on the insulating layer and including a plurality of second lattices having a second arrangement period, where the first lattice structure and the second lattice structure are spaced apart and the light-emitting structure layer is provided between the first lattice structure and the second lattice structure.

### CROSS-REFERENCE TO RELATED APPLICATION

This application is based on and claims priority under 35 U.S.C. §119 to Korean Patent Application No. 10-2023-0137037, filed on October 13, 2023, in the Korean Intellectual Property Office, the disclosure of which is incorporated by reference herein in its entirety.

### BACKGROUND

### Field

The disclosure relates to a light source and a silicon photonics system including the same.

### Description of Related Art

Silicon-photonics is used in a variety of ways because of advantages such as large-capacity information delivery, ultra-fast processing, minimal transmission loss, and energy consumption reduction.

It may be necessary to apply a laser light source with a single wavelength characteristic to manufacture a silicon photonics device. To this end, a method of securing the necessary short-wavelength characteristics is used in the related art by additionally applying a multi-section distributed feedback (DFB) structure to the laser light source. However, related art methods have difficulty in accurately aligning the DFB structure and the laser structure, and have limitations in short wavelength oscillation characteristics.

### SUMMARY

Provided are a short-wavelength light source and a silicon photonics system including the same.

Additional aspects will be set forth in part in the description which follows and, in part, will be apparent from the description, or may be learned by practice of the presented embodiments of the disclosure.

According to an aspect of an embodiment, a light source may include a silicon substrate including a groove, an insulating layer provided on the silicon substrate and including a trench above the groove, a buffer layer filling the groove of the silicon substrate and the trench of the insulating layer, a light-emitting structure layer provided on the buffer layer and including a quantum well structure layer, a first lattice structure provided on the insulating layer and including a plurality of first lattices having a first arrangement period, and a second lattice structure provided on the insulating layer and including a plurality of second lattices having a second arrangement period, where the first lattice structure and the second lattice structure are spaced apart and the light-emitting structure layer is provided between the first lattice structure and the second lattice structure.

The light source may be configured to emit light of a wavelength of about 950 nm to about 1750 nm based on the first arrangement period of the plurality of first lattices and the second arrangement period of the plurality of second lattices.

The first lattice structure and the second lattice structure may include Au, Ti, Ag, or Pt.

The quantum well structure layer may include a plurality of quantum barrier layers and a plurality of quantum well layers, which are alternately stacked, the plurality of quantum barrier layers may include at least one of In, Ga, Al, As, P, Si, Zn, and C, and the plurality of quantum well layers may include at least one of In, Ga, Al, As, P, Si, Zn, and C.

The plurality of quantum barrier layers may include InₓGaAl_{y}As, where 0.05≤x≤0.80, and 0.01≤y≤0.50, and the plurality of quantum well layers may include InₓGaAl_{y}As, where 0.05≤x≤0.80, and 0.01≤y≤0.50.

The light-emitting structure layer may include a first-type semiconductor layer and a second-type semiconductor layer, and the quantum well structure layer may be provided between the first-type semiconductor layer and the second-type semiconductor layer.

The light source may include a first clad layer provided between the first-type semiconductor layer and the quantum well structure layer, and a second clad layer provided between the first clad layer and the quantum well structure layer.

The first clad layer may include a material including a dopant of at least one of In, Ga, Al, As, P, Si, Zn, and C, and the second clad layer may include a material including a dopant of at least one of In, Ga, Al, As, P, Si, Zn, and C.

An inner side surface of the groove of the silicon substrate may include a Si(111) surface.

The groove of the silicon substrate may be V-shaped.

The light source may include an electrode layer provided on the light-emitting structure layer.

The insulating layer may include silicon oxide or silicon nitride.

The buffer layer may include a material that is a mixture of two or more of In, Ga, Al, As, and P.

According to an aspect of the disclosure, a silicon photonics system may include a light source and an optical waveguide through which light emitted from the light source travels, where the light source may include a silicon substrate including a groove, an insulating layer provided on the silicon substrate and including a trench above the groove, a buffer layer filling the groove of the silicon substrate and the trench of the insulating layer, a light-emitting structure layer provided on the buffer layer and including a quantum well structure layer, a first lattice structure provided on the insulating layer and including a plurality of first lattices having a first arrangement period, and a second lattice structure provided on the insulating layer and including a plurality of second lattices having a second arrangement period, where the first lattice structure and the second lattice structure are spaced apart, and the light-emitting structure layer is provided between the first lattice structure and the second lattice structure.

The silicon photonics system may include an optical modulator connected to the light source.

The silicon photonics system may include a photo detector connected to the light source.

The optical waveguide may include a beam splitter configured to branch light.

A light source may include a base layer including a groove, a first insulating layer, a second insulating layer provided above the first insulating layer and including a first trench, the first trench being above the groove, a buffer layer filling the groove and the first trench, a light-emitting structure layer provided on the buffer layer and including a quantum well structure layer, a first lattice structure provided on the second insulating layer and including a plurality of first lattices having a first arrangement period, and a second lattice structure provided on the second insulating layer and including a plurality of second lattices having a second arrangement period, where the first lattice structure and the second lattice structure are spaced apart and the light-emitting structure layer is provided between the first lattice structure and the second lattice structure.

The base layer may include a first portion below the first insulating layer and a second portion above the first insulating layer, the second insulating layer may be provided on the second portion of the base layer, and the second portion of the base layer may include the groove.

The second insulating layer may include a second trench spaced apart from the first trench, and the light source may include an optical waveguide provided in the second trench.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view illustrating a light source according to an embodiment;

FIG. 2 is a cross-sectional view illustrating the light source of FIG. 1 according to an embodiment;

FIG. 3 is a cross-sectional view illustrating the light source of FIG. 1 according to an embodiment;

FIG. 4 is a cross-sectional view illustrating the light source of FIG. 1 according to an embodiment;

FIGS. 5A to 5G are diagrams illustrating a method of manufacturing a light source according to an embodiment;

FIG. 6 is a perspective view illustrating a light source according to an embodiment;

FIG. 7 is a perspective view illustrating a silicon photonics system according to an embodiment;

FIG. 8 is a diagram illustrating a multi-wavelength light source according to an embodiment; and

FIG. 9 is a block diagram illustrating a configuration of a silicon photonics system according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

Hereinafter, a light source and a silicon photonics system including the same according to various embodiments will be described in detail with reference to the accompanying drawings. In the following drawings, the same reference numerals refer to the same components, and the size of each component in the drawings may be exaggerated for clarity and convenience of description. In addition, embodiments described below are merely illustrative, and various modifications are possible from these embodiments.

Hereinafter, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that it may further include other components, not excluding other components unless otherwise opposed.

The use of the term “the” and similar indicative terms may correspond to both singularity and plurality. Unless there is clear order or contrary description of the steps constituting the method, these steps may be performed in the appropriate order, and are not necessarily limited to the order described.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

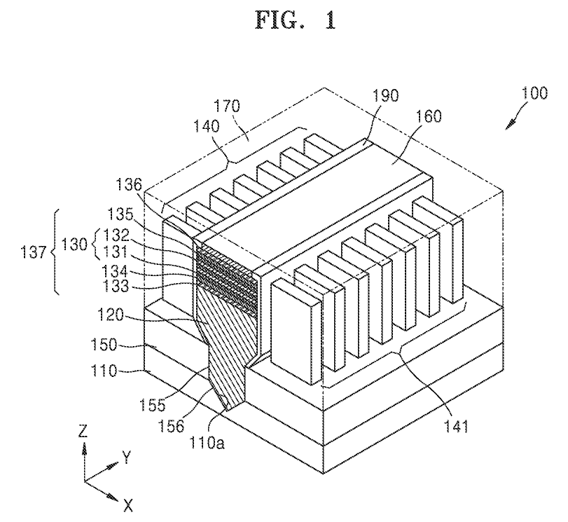

FIG. 1 is a perspective view illustrating a light source according to an embodiment.

Referring to FIG. 1, a light source 100 may include a silicon substrate 110, an insulating layer 150 provided on the silicon substrate 110 and having a trench 155, a buffer layer 120 provided to fill the trench 155 formed in the insulating layer 150, a light-emitting structure layer 137 provided on the buffer layer 120 and having a quantum well structure layer 130, and a first lattice structure 140 and a second lattice structure 141 spaced apart from each other on the insulating layer 150 with the light-emitting structure layer 137 therebetween.

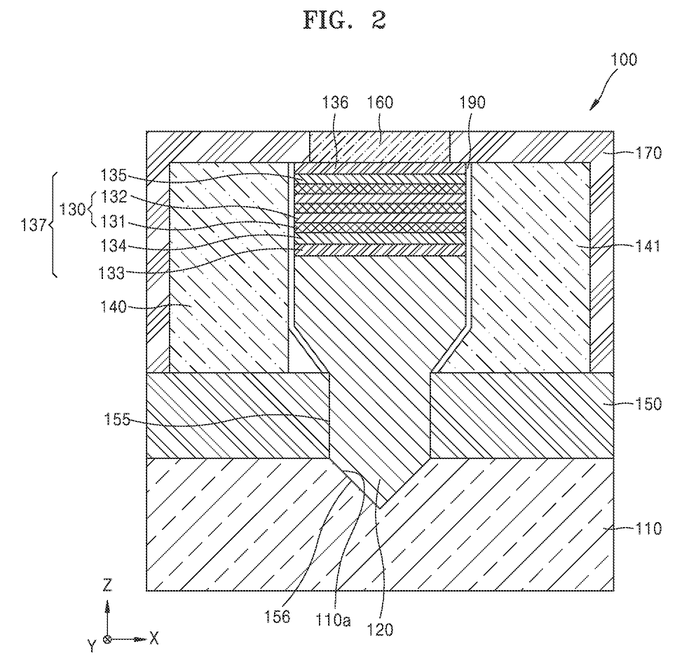

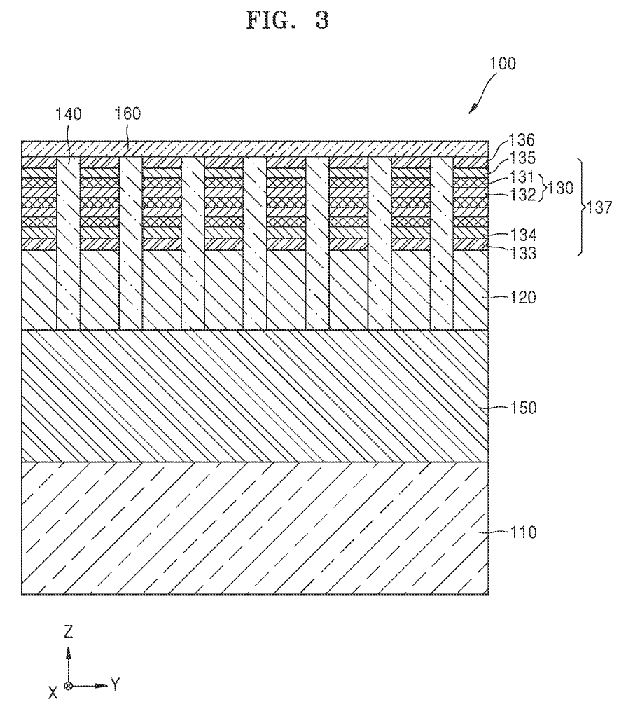

FIG. 2 is a cross-sectional view illustrating the light source of FIG. 1 according to an embodiment. FIG. 3 is a cross-sectional view illustrating the light source of FIG. 1 according to an embodiment. FIG. 2 is a cross-sectional view along the X-direction of FIG. 1, and FIG. 3 is a cross-sectional view along the Y-direction of FIG. 1

The silicon substrate 110 may include silicon. A groove 156 may be formed in the silicon substrate 110. The groove 156 of the silicon substrate 110 may be filled with the buffer layer 120. The silicon substrate 110 may include a V-shaped groove 156. The inner side surface of a V-shaped groove 156 of the silicon substrate 110 may include a Si(111) surface 110a (although the Si(111) surface 110a is shown on one side of the groove 156, this is for convenience of illustration due to the perspective, and the Si(111) surface 110a may be formed on both sides of the groove 156). In the Si(111) surface 110a of the silicon substrate 110, the buffer layer 120 including a material having a lattice constant different from that of silicon constituting the silicon substrate 110 may be bonded to the silicon substrate 110.

A trench 155 may be formed in the insulating layer 150. The trench 155 of the insulating layer 150 may be connected to the groove 156 of the silicon substrate 110. That is, the trench 155 may be formed above the groove 156, such that the trench 155 and the groove 156 form a channel. The trench 155 of the insulating layer 150 may be filled with the buffer layer 120. The insulating layer 150 may include silicon oxide or silicon nitride. The insulating layer 150 may include, for example, SiO₂ or Si₃N₄. A thickness of the insulating layer 150 may be, for example, about 100 nm or more.

The buffer layer 120 may include a material obtained by mixing (i.e., a mixture of) two or more of In, Ga, Al, As, and P. The buffer layer 120 may include a multilayer structure in which two or more materials among In, Ga, Al, As, and P are mixed. The buffer layer 120 may include a group III-Ⅴ semiconductor material. The buffer layer 120 may include, for example, GaAs, InGaAs, or InP. However, the buffer layer 120 is not limited thereto. The V-shaped groove 156 of the silicon substrate 110 may be filled with the buffer layer 120. The trench 155 formed in the insulating layer 150 may be filled with the buffer layer 120.

The light-emitting structure layer 137 including a quantum well structure may be provided on the buffer layer 120. The light-emitting structure layer 137 may include a first-type semiconductor layer 133, a first clad layer 134, a quantum well structure layer 130, a second clad layer 135, and a second-type semiconductor layer 136. The first-type semiconductor layer 133, the first clad layer 134, the quantum well structure layer 130, the second clad layer 135, and the second-type semiconductor layer 136 may be sequentially stacked on the buffer layer 120. Each of the buffer layer 120, the first-type semiconductor layer 133, the first clad layer 134, the quantum well structure layer 130, the second clad layer 135, and the second-type semiconductor layer 136 may be formed by, for example, organic metal chemical vapor deposition (MOCVD). The first-type semiconductor layer 133, the first clad layer 134, the quantum well structure layer 130, the second clad layer 135, and the second-type semiconductor layer 136 formed on the buffer layer 120 may form a p-i-n junction structure for optical modulation, where the quantum well structure layer 130 is not doped with a dopant and may form an intrinsic (i)-region.

The first-type semiconductor layer 133 may be arranged below the quantum well structure layer 130. The first-type semiconductor layer 133 may include InP. The first-type semiconductor layer 133 is not limited to InP and may vary depending on a material of the buffer layer 120. For example, the first-type semiconductor layer 133 may include InGaAs, InGaAlAs, or InGaAsP. The first-type semiconductor layer 133 may include a first-type dopant, and for example, an n-type dopant may be doped into InP. As the n-type dopant, Si, C, Ge, Se, or Te may be used, for example. However, the embodiments are not limited thereto, and the first-type semiconductor layer 133 may include a p-type dopant, and Zn or Mg may be used as the p-type dopant.

The first clad layer 134 may be provided in the first-type semiconductor layer 133. The first clad layer 134 may be arranged below the quantum well structure layer 130. The first clad layer 134 may be arranged between the first-type semiconductor layer 133 and the quantum well structure layer 130. The first clad layer 134 and the second clad layer 135 to be described later may be configured to constrain the light incident on the quantum well structure layer 130. The first clad layer 134 and the second clad layer 135 may be referred to as a separated confinement heterostructure (SCH) layer. The first clad layer 134 and the second clad layer 135 may additionally be configured for current diffusion. Thicknesses of the first clad layer 134 and the second clad layer 135 may each independently be, for example, about 0.01 μm to about 1 μm (i.e., the first clad layer 134 may have a thickness that is different from the second clad layer 135, and both the first clad layer 134 and the second clad layer 135 may have a thickness of about 0.01 μm to about 1 μm).

The first clad layer 134 may include, for example, a material including a predetermined dopant of at least one of In, Ga, Al, As, P, Si, Zn, and C. The first clad layer 134 may include, for example, a material including a predetermined dopant of InGaAs, InGaAlAs, InGaAsP, or InP. The first clad layer 134 may have a dopant concentration lower than the first-type semiconductor layer 133.

When the first-type semiconductor layer 133 is an n-type, the first clad layer 134 may be an n-type clad layer. In this case, the first clad layer 134 may include, for example, an n-type dopant such as Si, C, Ge, Se, Te, or the like. When the first-type semiconductor layer 133 is a p-type, the first clad layer 134 may be a p-type clad layer. In this case, the first clad layer 134 may include, for example, a p-type dopant such as Zn, Mg, etc.

The quantum well structure layer 130 may be provided on the first clad layer 134. The wavelength of light may be determined by a combination of semiconductor materials forming the quantum well structure layer 130. For example, the quantum well structure layer 130 may emit light in a wavelength range about 950 nm to about 1750 nm.

The quantum well structure layer 130 may include a multi-quantum well structure. The quantum well structure layer 130 may include a quantum barrier layer 131 and a quantum well layer 132. The quantum well structure layer 130 may include a plurality of quantum barrier layers 131 and a plurality of quantum well layers 132, which are alternately stacked. The quantum barrier layer 131 and the quantum well layer 132 (or the plurality of quantum barrier layers 131 and the plurality of quantum well layers 132) may independently include at least one of In, Ga, Al, As, P, Si, Zn, and C (i.e., each of the layers may include a material that is the same as or different from other layers). The quantum barrier layer 131 and the quantum well layer 132 (or the plurality of quantum barrier layers 131 and the plurality of quantum well layers 132) may independently include InₓGaAl_{y}As where 0.05≤x≤0.80, and 0.01≤y≤0.50 (i.e., each of the layers may include InₓGaAl_{y}As in an amount that is the same as or different from other layers).

The emission wavelength band may be adjusted by changing at least one of the shape, material, and thickness of the quantum well layer 132, and the emission intensity may be adjusted by changing the number of layers of the quantum well layer 132.

Each of the quantum barrier layers 131 may be formed, for example, to have a thickness of about 3 nm to about 50 nm, and each of the quantum well layers 132 may be formed, for example, to have a thickness of about 3 nm to about 25 nm. However, this is merely an example, and the quantum barrier layer 131 and the quantum well layer 132 may be formed in various thicknesses.

The second clad layer 135 may be provided on the quantum well structure layer 130. The second clad layer 135 may be arranged between the second-type semiconductor layer 136 and the quantum well structure layer 130. As described above, the second clad layer 135 may be configured to constrain the light incident on the quantum well structure layer 130, and may additionally function to distribute electrical current.

The second clad layer 135 may include, for example, a material including a predetermined dopant of at least one of In, Ga, Al, As, P, Si, Zn, and C. The second clad layer 135 may include, for example, a material including a predetermined dopant in InGaAs, InGaAlAs, InGaAsP, or InP. The second clad layer 135 may have a dopant concentration lower than the second-type semiconductor layer 136.

When the second-type semiconductor layer 136 is a p-type, the second clad layer 135 may be a p-type clad layer. In this case, the second clad layer 135 may include, for example, a p-type dopant such as Zn, Mg, etc. When the second-type semiconductor layer 136 is an n-type, the second clad layer 135 may be an n-type clad layer. In this case, the second clad layer 135 may include, for example, an n-type dopant such as Si, C, Ge, Se, Te, or the like.

The second-type semiconductor layer 136 may be provided on the second clad layer 135. The second-type semiconductor layer 136 may include InP. However, the second-type semiconductor layer 136 is not limited thereto, and for example, the second-type semiconductor layer 136 may include InGaAs, InGaAlAs, or InGaAsP. The second-type semiconductor layer 136 may include a second-type dopant, and may include, for example, a p-type dopant. As the p-type dopant, Zn or Mg may be used, for example.

An electrode layer 160 may be provided on an upper portion of the light-emitting structure layer 137. The electrode layer 160 may include a metal material. The electrode layer 160 may include, for example, a metal having high conductivity or various conductive materials.

A protective layer 190 surrounding the buffer layer 120, the light-emitting structure layer 137, and the electrode layer 160 may be provided. The protective layer 190 may include, for example, InGaP.

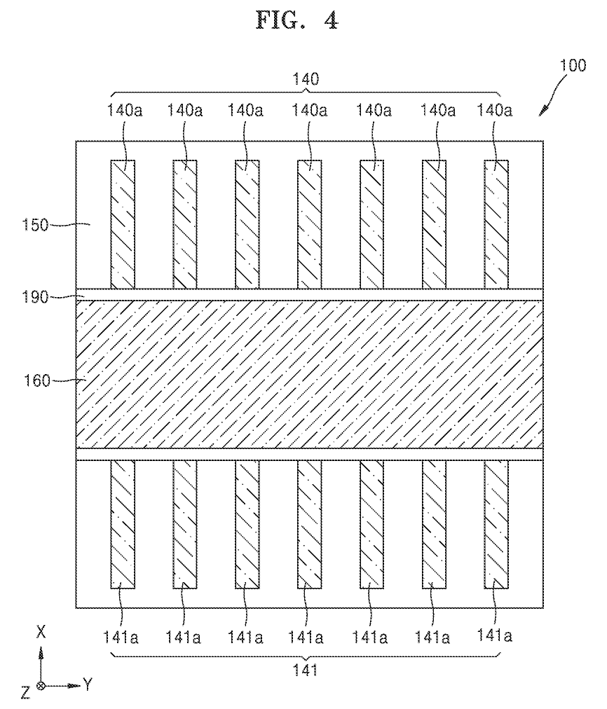

FIG. 4 is a cross-sectional view illustrating the light source of FIG. 1 according to an embodiment. FIG. 4 is a cross-sectional view along the Z-direction of FIG. 1 (i.e., FIG. 4 is a cross-sectional plan view of the light source 100).

Referring to FIG. 4, a first lattice structure 140 may include a plurality of first lattices 140a periodically arranged, and a second lattice structure 141 may include a plurality of second lattices 141a periodically arranged. The light source 100 may include the first lattice structure 140 including the plurality of periodically arranged first lattices 140a and the second lattice structure 141 including the plurality of periodically arranged second lattices 141a. That is, the periodic arrangement may indicate that each of the plurality of first lattices 140a may be spaced apart at equal or substantially equal intervals/distances, and each of the plurality of second lattices 141a may be spaced apart at equal or substantially equal intervals/distances. Each of the plurality of first lattices 140a and the plurality of second lattices 141a may be arranged in parallel with each other at an interval in the first direction (e.g., the Y direction), and may extend in the second direction (e.g., the X direction). Although the first lattice structure 140 is illustrated to include seven first lattices 140a, and the second lattice structure 141 is illustrated to include seven second lattices 141a, the embodiments are not limited thereto.

The first lattice structure 140 and the second lattice structure 141 may be arranged on the insulating layer 150. The plurality of first lattices 140a constituting the first lattice structure 140 may be arranged at a predetermined period. That is, the plurality of first lattices 140a constituting the first lattice structure 140 may be arranged at the same interval. The plurality of second lattices 141a constituting the second lattice structure 141 may be arranged at a predetermined period. That is, the plurality of second lattices 141a constituting the second lattice structure 141 may be arranged at the same interval. The arrangement period of the plurality of first lattices 140a constituting the first lattice structure 140 may be the same as the arrangement period of the plurality of second lattices 141a constituting the second lattice structure 141.

The first lattice structure 140 and the second lattice structure 141 may be arranged to face both side surfaces of the light-emitting structure layer 137 in the second direction (e.g., the X direction). The first lattice structure 140 and the second lattice structure 141 may be arranged to be spaced apart from each other with the light-emitting structure layer 137 therebetween. In other words, the light-emitting structure layer 137 may be provided between the first lattice structure 140 and the second lattice structure 141. The first lattice structure 140 and the second lattice structure 141 may be arranged on both sides of the light-emitting structure layer 137 in the second direction (e.g., the X direction). The first lattice structure 140 and the second lattice structure 141 may be arranged on both sides of the light-emitting structure layer 137 in the horizontal direction (e.g., the X direction).

Short-wavelength characteristics of the light source 100 may be secured through the first lattice structure 140 and the second lattice structure 141. The arrangement periods of the first lattice structure 140 and the second lattice structure 141 may determine the characteristic wavelength of the light source 100. The arrangement period of the first lattice structure 140 may refer to an arrangement period of the plurality of first lattices 140a constituting the first lattice structure 140, and the arrangement period of the second lattice structure 141 may refer to an arrangement period of the plurality of second lattices 141a constituting the second lattice structure 141. As the plurality of first lattice structures 140 and the plurality of second lattice structures 141 are arranged at regular intervals, the light source 100 may emit only light of a specific wavelength. That is, the light source 100 emitting light of a desired wavelength may be implemented by adjusting the arrangement periods of the plurality of first lattice structures 140 and the plurality of second lattice structures 141. Specifically, by adjusting the distance between the plurality of first lattice structures 140 and the plurality of second lattice structures 141 adjacent to each other to 1/4 times the desired wavelength in consideration of the refractive index of the applied material, the light source 100 that emits light of the desired wavelength may be implemented. For example, the arrangement periods of the first lattice structure 140 and the second lattice structure 141 may be set so that the wavelength of light emitted from the light source is about 950 nm to about 1750 nm.

The first lattice structure 140 and the second lattice structure 141 may include a metal material. The first lattice structure 140 and the second lattice structure 141 may include, for example, Au, Ti, Ag, or Pt. However, the first lattice structure 140 and the second lattice structure 141 are not limited thereto.

A passivation layer 170 covering the first lattice structure 140 and the second lattice structure 141 may be formed. The passivation layer 170 may include various insulating materials, for example, oxides such as SiO₂, HfOₓ, and Al₂O₃.

The light source 100 may be a short-wavelength infrared laser. The light source 100 may provide light in an infrared wavelength band. The light source 100 may be, for example, a laser that emits light in a wavelength band of about 950 nm to about 1750 nm. The first lattice structure 140 and the second lattice structure 141 may be referred to as a multi-section distributed feedback (DFB) structure. The light source 100 may be a multi-section DFB laser including the first lattice structure 140 and the second lattice structure 141.

In the light source 100 according to an embodiment, the characteristic wavelength of the light source 100 may be adjusted by adjusting the arrangement periods of the first lattice structure 140 and the second lattice structure 141. In addition, the first lattice structure 140 and the second lattice structure 141 are arranged facing both sides of the light-emitting structure layer 137, respectively, so that the electrode layer 160 may be applied on the light-emitting structure layer 137, and accordingly, direct driving current may be applied to the light-emitting structure layer 137.

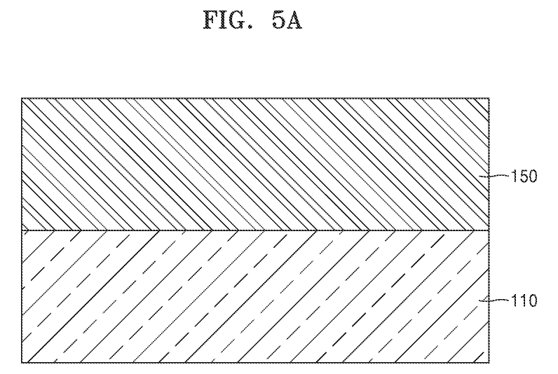

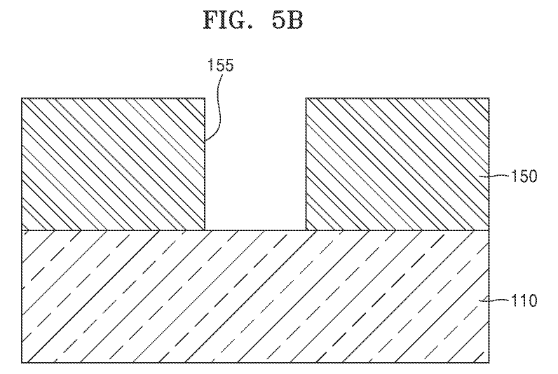

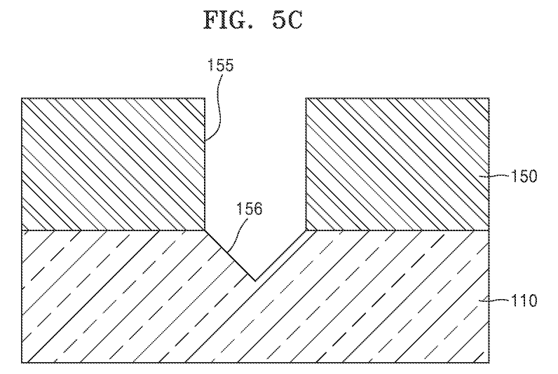

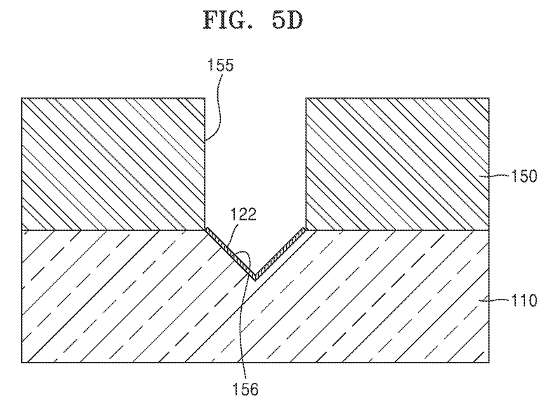

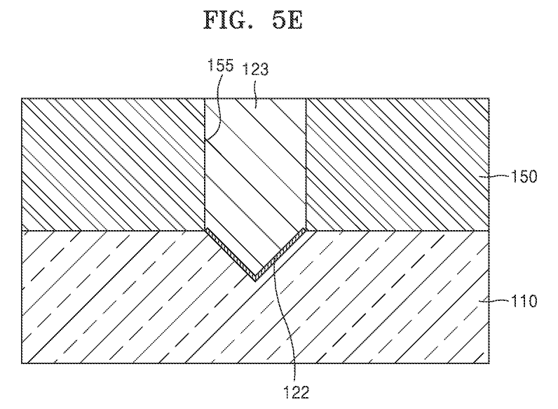

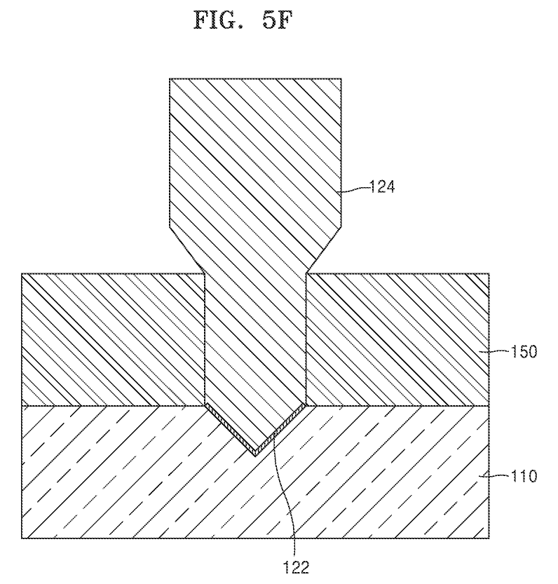

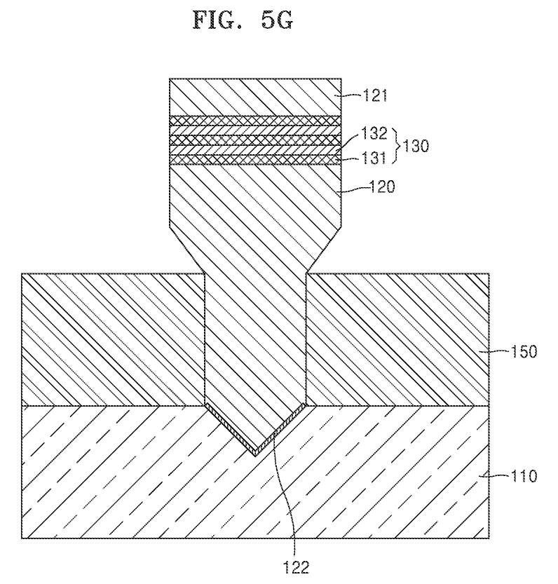

FIGS. 5A to 5G are diagrams illustrating a method of manufacturing a light source according to an embodiment.

Referring to FIG. 5A, an insulating layer 150 may be formed on a silicon substrate 110. The silicon substrate 110 and the insulating layer 150 may be the same as or similar to the silicon substrate 110 and the insulating layer 150 of FIG. 1.

Referring to FIG. 5B, a trench 155 may be formed by etching the insulating layer 150. An operation of etching the insulating layer 150 to form a trench 155 may be performed via a dry etching process.

Referring to FIG. 5C, a V-shaped groove 156 may be formed by etching the silicon substrate 110. An operation of etching the silicon substrate 110 to form a V-shaped groove 156 may be performed via a wet etching process. The wet etching process may be performed, for example, using a KOH or TMAH solution as an etching medium.

Referring to FIG. 5D, a seed layer 122 may be formed in the V-shaped groove 156 of the silicon substrate 110. The seed layer 122 may include a material obtained by mixing two or more of In, Ga, Al, As, and P. The seed layer 122 may include a group III-Ⅴ semiconductor material. The seed layer 122 may include, for example, GaAs. The seed layer 122 may be formed, for example, on a Si(111) surface.

Referring to FIG. 5E, an aspect ratio trapping (ART) layer 123 may be formed on the seed layer 122. The ART layer 123 may be formed to fill the trench 155 of the insulating layer 150. The ART layer 123 may include the same material as the seed layer 122. The ART layer 123 may include, for example, GaAs.

Referring to FIG. 5F, a nano-ridge epitaxy (NRE) layer 124 may be formed by crystal-growing the ART layer 123. The NRE layer 124 may include the same material as the seed layer 122 and the ART layer 123. The NRE layer 124 may include, for example, GaAs.

Referring to FIG. 5G, a quantum well structure layer 130 may be formed inside the NRE layer 124. A buffer layer 120 may be formed below the quantum well structure layer 130, and a second buffer layer 121 may be formed above the quantum well structure layer 130. The buffer layer 120 and the second buffer layer 121 may include the same material as the NRE layer 124.

According to the manufacturing method of some embodiments, a group III-semiconductor material having a lattice constant different from silicon may be directly formed on silicon by forming the V-shaped groove 156 on the silicon substrate.

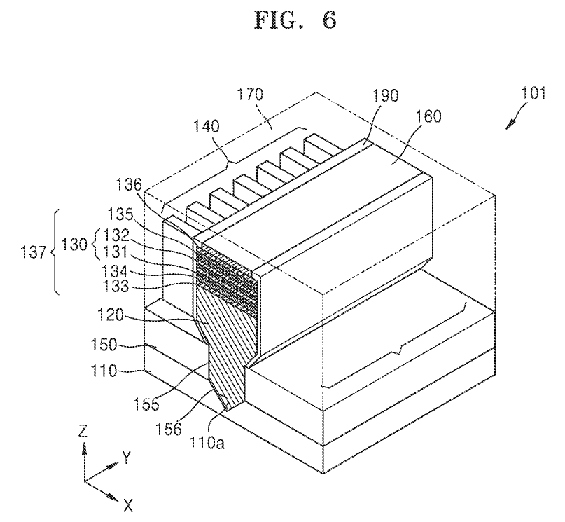

FIG. 6 is a perspective view illustrating a light source according to an embodiment.

Referring to FIG. 6, a light source 100 may include a silicon substrate 110, an insulating layer 150 provided on the silicon substrate 110 and having a trench 155, a buffer layer 120 provided to fill the trench 155 formed in the insulating layer 150, a light-emitting structure layer 137 provided on the buffer layer 120 and having a quantum well structure layer 130, and a lattice structure 140 arranged on the insulating layer 150 on one side of the light-emitting structure layer 137 in the horizontal direction (e.g., the X direction).

The lattice structure 140 may be the same as or similar to the first lattice structure 140 of FIGS. 1 to 4. The lattice structure 140 may be arranged on one surface of the light-emitting structure layer 137. The lattice structure 140 may be arranged on one side of the light-emitting structure layer 137 in a second direction (e.g., the X direction). The lattice structure 140 may be arranged on one side of the light-emitting structure layer 137 in a horizontal direction (e.g., the X direction). The lattice structure 140 is shown to be arranged on the left side of the light-emitting structure layer 137 on the XZ plane, but is not limited thereto. The lattice structure 140 may be arranged on the right side of the light-emitting structure layer 137 on the XZ plane.

The light source 101 may be the same as or similar the light source 100 of FIGS. 1 to 4, except that the lattice structure 140 may be arranged on only one surface of the light-emitting structure layer 137. Therefore, redundant descriptions of FIGS. 1 to 4 may be omitted.

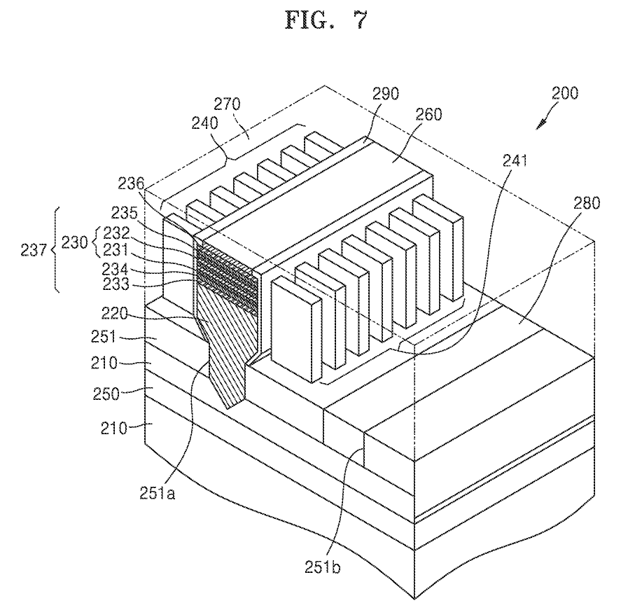

FIG. 7 is a perspective view illustrating a silicon photonics system according to an embodiment.

Referring to FIG. 7, a silicon photonics system 200 may include a base layer 210, a first insulating layer 250 arranged in the base layer 210 such that the first insulating layer 250 is arranged inside the base layer 210 (i.e., the base layer 210 may include a first portion below the first insulating layer 250 and a second portion above the first insulating layer 250), a second insulating layer 251 arranged on the base layer 210 and above the first insulating layer 250, and provided with a first trench 251a and a second trench 251b (alternatively, the first insulating layer 250 may be arranged on the base layer 210, and the second insulating layer 251 may be arranged on (i.e., directly on) the first insulating layer 250), a buffer layer 220 provided in the first trench 251a of the second insulating layer 251, a light-emitting structure layer 237 arranged on the buffer layer 220 and having a quantum well structure layer 230, a first lattice structure 240 and a second lattice structure 241 arranged on the second insulating layer 251, and an optical waveguide 280.

The buffer layer 220, the quantum well structure layer 230, the light-emitting structure layer 237, the quantum barrier layer 231, the quantum well layer 232, the first-type semiconductor layer 233, the first clad layer 234, the second clad layer 235, the second-type semiconductor layer 236, the first lattice structure 240, and the second lattice structure 241 of FIG. 7 may be the same as or similar to the buffer layer 120, the quantum well structure layer 130, the light-emitting structure layer 137, the quantum barrier layer 131, the quantum well layer 132, the first-type semiconductor layer 133, the first clad layer 134, the second clad layer 135, the second-type semiconductor layer 136, the first lattice structure 140, and the second lattice structure 141 of FIGS. 1 to 4. Therefore, redundant descriptions of FIGS. 1 to 4 may be omitted.

The base layer 210 may include silicon. The first insulating layer 250 arranged on the base layer 210 may include silicon oxide. The first insulating layer 250 may include, for example, SiO₂. The base layer 210 and the first insulating layer 250 may be collectively referred to as a silicon on insulator (SoI) substrate. In the SoI substrate, the first insulating layer 250 is arranged inside the base layer 210 to improve efficiency and characteristics of the base layer 210.

The second insulating layer 251 may include silicon oxide or silicon nitride. The second insulating layer 251 may include, for example, SiO₂ or Si₃N₄.

An electrode layer 260 may be provided on the light-emitting structure layer 237. The electrode layer 260 may be made of a metal having high conductivity or various conductive materials. A protective layer 290 surrounding the buffer layer 220, the light-emitting structure layer 237, and the electrode layer 260 may be provided. The protective layer 290 may include, for example, InGaP.

The base layer 210, the first insulating layer 250, the second insulating layer 251, the buffer layer 220, the light-emitting structure layer 237, the first lattice structure 240, the second lattice structure 241, and the electrode layer 260 may be collectively referred to as a light source.

The optical waveguide 280 may be provided in the second trench 251b formed in the second insulating layer 251. Light emitted from the light source may travel through the optical waveguide 280. Light emitted from the light source may be transmitted to the optical waveguide 280 using optical coupling. Due to coherence of the light source, the light source may transfer energy to the adjacent optical waveguide 280. The optical waveguide 280 may include silicon. An amplifier may be arranged in the optical waveguide 280. The amplifier may amplify an output of light.

A passivation layer 270 covering the light source and the optical waveguide 280 may be formed. The passivation layer 270 may include various kinds of insulating materials, for example, oxides such as SiO₂, HfOₓ, and Al₂O₃.

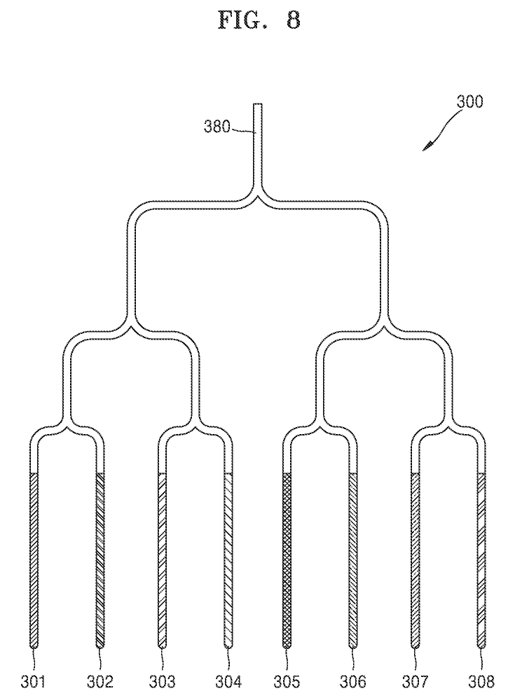

FIG. 8 is a diagram illustrating a multi-wavelength light source according to an embodiment.

Referring to FIG. 8, a multi-wavelength light source 300 may include a plurality of short-wavelength light sources 301 to 308. Each of the short-wavelength light sources 301 to 308 may have the same structure as the light source 100 of FIGS. 1 to 4, the light source 101 of FIG. 6, and/or the light source of FIG. 7. The plurality of short-wavelength light sources 301 to 308 may include a lattice structure including a plurality of lattices, and arrangement periods of the plurality of lattices constituting the lattice structure may be different from each other.

A plurality of short-wavelength light sources 301 to 308 may emit light having different wavelengths. Power may be independently applied to each of the short-wavelength light sources 301 to 308. Eight different short-wavelength light sources 301 to 308 having different arrangement periods of the plurality of lattices constituting the lattice structure may be connected to one optical waveguide 380 and used as the multi-wavelength light source 300.

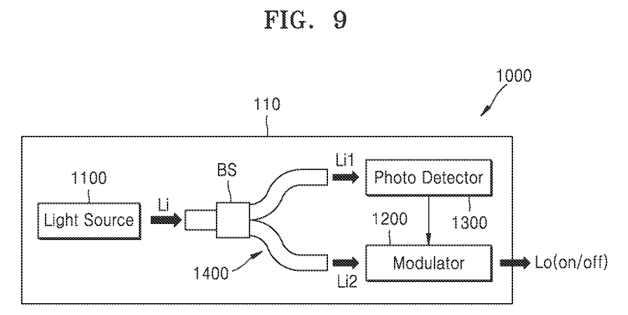

FIG. 9 is a block diagram illustrating a configuration of a silicon photonics system according to an embodiment.

Referring to FIG. 9, a silicon photonics system 1000 may include a silicon substrate 110, a light source 1100 provided on the silicon substrate 110, and an optical waveguide 1400 through which light from the light source 1100 travels.

The silicon photonics system 1000 may include an optical modulator 1200 and a photo detector 1300 provided on the silicon substrate 110 and electrically connected to the light source 1100.

The light source 1100 may be the same as or similar to the light source 100 described with reference to FIGS. 1 to 4, the light source 101 of FIG. 6, and/or the light source of FIG. 7. The photo detector 1300 may include a photo detector having various structures for generating an electrical signal by absorbing infrared rays. The optical waveguide 1400 may be provided in the silicon substrate 110. The optical waveguide 1400 may branch the incident light Li into light Li1 and light Li2 and provide the same to each of the optical modulator 1200 and the photo detector 1300. The optical waveguide 1400 may include a beam splitter BS for optical branching. The beam splitter BS may branch the incident light into two branches, and in this case, the branching ratios may be the same or different from each other.

A predetermined output light Lo may be output according to input light Li1 and Li2 incident on the optical modulator 1200 and the photo detector 1300 along the optical waveguide 1400 from the light source 1100. The output light Lo may be controlled to be on/off, or on/off may be defined according to the intensity of the output light Lo. Li1 and Li2 may be infrared rays, for example, light having a wavelength of about 1550 nm. However, this is merely an example. The input light Li1 is incident on the photo detector 1300, and accordingly, an electrical signal may be generated in the photo detector 1300. The electrical signal generated by the photo detector 1300 in response to the input light Li1 is input to the optical modulator 1200. The optical modulator 1200 may modulate (turn on/off) the input light Li2 according to the applied voltage.

In this way, the electrical signal generated by the photo detector 1300 depends on the intensity of Li1, and whether Li2 is output by the photo detector 1300 depends on the electrical signal generated by the photo detector 1300. That is, a predetermined output signal Lo may be generated from the light source 1100 according to the input light Li1 and Li2 incident on the optical modulator 1200 and the photo detector 1300.

In the light source and the silicon photonics system including the same according to embodiments, the characteristic wavelength of the light source may be determined according to the arrangement period of the lattice structure. The light source and the silicon photonics system including the same have been described with reference to the embodiments shown in the drawings. According to the disclosed embodiments, a light source may be provided whose characteristic wavelength is determined according to the arrangement period of the lattice structure.

According to the disclosed embodiments, a light source capable of directly applying a driving current may be provided by arranging a light-emitting structure layer between the lattice structures.

According to the disclosed embodiments, a silicon photonics system may be provided including a light source capable of directly applying a driving current and determining a characteristic wavelength by a lattice structure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light source comprising:
a silicon substrate comprising a groove;
an insulating layer provided on the silicon substrate and comprising a trench above the groove;
a buffer layer filling the groove of the silicon substrate and the trench of the insulating layer;
a light-emitting structure layer provided on the buffer layer and comprising a quantum well structure layer;
a first lattice structure provided on the insulating layer and comprising a plurality of first lattices having a first arrangement period;
a second lattice structure provided on the insulating layer and comprising a plurality of second lattices having a second arrangement period,
wherein the first lattice structure and the second lattice structure are spaced apart, and
wherein the light-emitting structure layer is provided between the first lattice structure and the second lattice structure.

2. The light source of claim 1, wherein the light source is configured to emit light of a wavelength of about 950 nm to about 1750 nm based on the first arrangement period of the plurality of first lattices and the second arrangement period of the plurality of second lattices.

3. The light source of claim 1, wherein the first lattice structure and the second lattice structure comprise Au, Ti, Ag, or Pt.

4. The light source of claim 1, wherein the quantum well structure layer comprises a plurality of quantum barrier layers and a plurality of quantum well layers, which are alternately stacked,
wherein the plurality of quantum barrier layers comprise at least one of In, Ga, Al, As, P, Si, Zn, and C, and
wherein the plurality of quantum well layers comprise at least one of In, Ga, Al, As, P, Si, Zn, and C.

5. The light source of claim 4, wherein the plurality of quantum barrier layers comprise InₓGaAl_{y}As, where 0.05≤x≤0.80, and 0.01≤y≤0.50, and
wherein the plurality of quantum well layers comprise InₓGaAl_{y}As, where 0.05≤x≤0.80, and 0.01≤y≤0.50.

6. The light source of claim 1, wherein the light-emitting structure layer comprises a first-type semiconductor layer and a second-type semiconductor layer, and
wherein the quantum well structure layer is provided between the first-type semiconductor layer and the second-type semiconductor layer.

7. The light source of claim 6, further comprising:
a first clad layer provided between the first-type semiconductor layer and the quantum well structure layer; and
a second clad layer provided between the first clad layer and the quantum well structure layer.

8. The light source of claim 7, wherein the first clad layer comprises a material comprising a dopant of at least one of In, Ga, Al, As, P, Si, Zn, and C, and
wherein the second clad layer comprises a material comprising a dopant of at least one of In, Ga, Al, As, P, Si, Zn, and C.

9. The light source of claim 1, wherein an inner side surface of the groove of the silicon substrate comprises a Si(111) surface.

10. The light source of claim 1, wherein the groove of the silicon substrate is V-shaped.

11. The light source of claim 1, further comprising an electrode layer provided on the light-emitting structure layer.

12. The light source of claim 1, wherein the insulating layer comprises silicon oxide or silicon nitride.

13. The light source of claim 1, wherein the buffer layer comprises a material that is a mixture of two or more of In, Ga, Al, As, and P.

14. A silicon photonics system comprising:
a light source; and
an optical waveguide through which light emitted from the light source travels,
wherein the light source comprises:
a silicon substrate comprising a groove;
an insulating layer provided on the silicon substrate and comprising a trench above the groove;
a buffer layer filling the groove of the silicon substrate and the trench of the insulating layer;
a light-emitting structure layer provided on the buffer layer and comprising a quantum well structure layer;
a first lattice structure provided on the insulating layer and comprising a plurality of first lattices having a first arrangement period; and
a second lattice structure provided on the insulating layer and comprising a plurality of second lattices having a second arrangement period,
wherein the first lattice structure and the second lattice structure are spaced apart, and
wherein the light-emitting structure layer is provided between the first lattice structure and the second lattice structure.

15. The silicon photonics system of claim 14, further comprising an optical modulator connected to the light source.

16. The silicon photonics system of claim 14, further comprising a photo detector connected to the light source.

17. The silicon photonics system of claim 14, wherein the optical waveguide comprises a beam splitter configured to branch light.

18. A light source, comprising:
a base layer comprising a groove;
a first insulating layer;
a second insulating layer provided above the first insulating layer and comprising a first trench, the first trench being above the groove;
a buffer layer filling the groove and the first trench;
a light-emitting structure layer provided on the buffer layer and comprising a quantum well structure layer;
a first lattice structure provided on the second insulating layer and comprising a plurality of first lattices having a first arrangement period; and
a second lattice structure provided on the second insulating layer and comprising a plurality of second lattices having a second arrangement period,
wherein the first lattice structure and the second lattice structure are spaced apart, and
wherein the light-emitting structure layer is provided between the first lattice structure and the second lattice structure.

19. The light source of claim 18, wherein the base layer comprises a first portion below the first insulating layer and a second portion above the first insulating layer,
wherein the second insulating layer is provided on the second portion of the base layer, and
wherein the second portion of the base layer comprises the groove.

20. The light source of claim 18, wherein the second insulating layer further comprises a second trench spaced apart from the first trench, and
wherein the light source further comprises an optical waveguide provided in the second trench.
